(19) United States
(12) Patent Application Publication
(10) Pub. No.: US 2026/0107621 A1
(43) Pub. Date: Apr. 16, 2026

(54) Light-Emitting Device

(71) Applicant: LITE-ON TECHNOLOGY CORPORATION, Taipei (TW)

(72) Inventors: Wen-Hsiang LIN, Taipei (TW); Kai-Yu HSIEH, Taipei (TW)

(21) Appl. No.: 18/912,654

(22) Filed: Oct. 11, 2024

Related U.S. Application Data
(60) Provisional application No. 63/610,031, filed on Dec. 14, 2023.

(30) Foreign Application Priority Data
May 6, 2024 (CN) 202410548838.8

(51) Int. Cl. H10H 29/856; H10H 20/851; H10H 29/24; H10H 29/85; H10H 29/855

(52) U.S. Cl. CPC H10H 29/856; H10H 20/851; H10H 29/24; H10H 29/8552; H10H 29/8508

(57) ABSTRACT

A light-emitting device is provided. The light-emitting device includes a substrate, a reflection layer on the substrate, a plurality of light-emitting elements on the substrate and in the reflection layer, and a plurality of light transmitting elements on a plurality of light-emitting elements and in the reflection layer. A plurality of upper surfaces of a plurality of light transmitting elements are exposed by the reflection layer. There is a first micrometer scale pitch between adjacent two light transmitting elements of a plurality of light transmitting elements. The reflection layer includes a light reflection material and a light absorption material.

This application claims the benefit of U.S. provisional application Ser. No. 63/610,031, filed Dec. 14, 2023, and People's Republic of China application Serial No. 202410548838.8, filed May 6, 2024, the subject matters of which are incorporated herein by reference.

### BACKGROUND

### Technical Field

The disclosure relates to a light-emitting device.

### Description of the Related Art

Light-emitting diode (LED) is a semiconductor light-emitting element, and has been widely used in various fields, such as lighting devices and display devices.

Led headlamp for car, especially the adaptive driving beam headlamp (ADB) for car, is a light-emitting device including a plurality of LED chips and a reflection resin filled between LED chips. However, with the trend to minimize the light-emitting device, pitch between LED chips continues to shrink, resulting in the thickness of the reflection layer formed by commercially available reflection resin being insufficient to fully reflect the light emitted by the LED chips and the light penetrating the reflection layer. As such, the brightness and contrast of the device are reduced.

### SUMMARY

According to some embodiments of the present disclosure, a light-emitting device is provided. The light-emitting device includes a substrate, a reflection layer, a plurality of light-emitting elements, and a plurality of light transmitting elements. The reflection layer is on the substrate. A plurality of light-emitting elements are on the substrate and in the reflection layer. A plurality of light transmitting elements are on a plurality of light-emitting elements and in the reflection layer, wherein a plurality of upper surfaces of a plurality of light transmitting elements are exposed by the reflection layer, and there is a first micrometer scale pitch between adjacent two light transmitting elements of a plurality of light transmitting elements. The reflection layer includes a light reflection material and a light absorption material.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic view of a light-emitting device according to an embodiment of the present disclosure.

FIG. 2 illustrates a schematic cross-sectional view of a light-emitting device according to an embodiment of the present disclosure.

FIG. 3 shows a contrast graph of a light-emitting device according to an embodiment of the present disclosure.

FIG. 4 illustrates a schematic cross-sectional view of a light-emitting device according to another embodiment of the present disclosure.

FIG. 5 illustrates a schematic top view of a light-emitting device according to an embodiment of the present disclosure.

FIG. 6 illustrates the measurement method of a light-emitting device according to an embodiment of the present disclosure.

### DETAILED DESCRIPTION

Various embodiments will be described more fully hereinafter with reference to accompanying drawings, which are provided for illustrative and explaining purposes rather than a limiting purpose. For clarity, the drawings may be simplified, and the components may not be drawn to scale. The drawings use the same/similar reference numerals to indicate the same/similar elements. As used in the specification and the appended claims, ordinals such as “first”, “second” and the like to describe elements do not imply or represent a specific position in the structure, or the order of arrangement, or the order of manufacturing. The ordinals are only used to clearly distinguish multiple elements with the same name.

As used in the specification and the appended claims, term “micrometer scale” represents a size on the micrometer scale, such as between 1 μm to 100 μm.

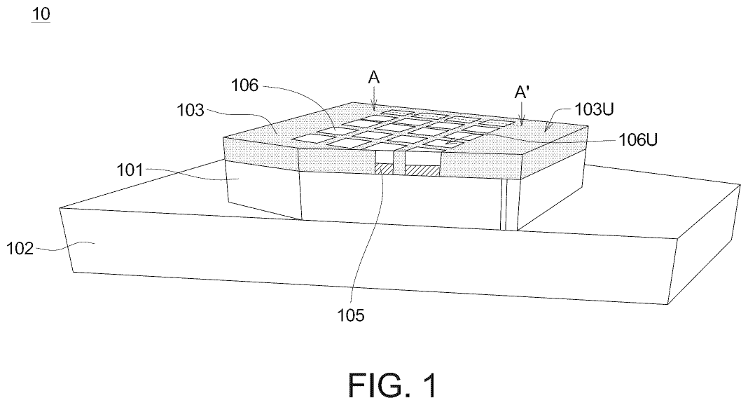

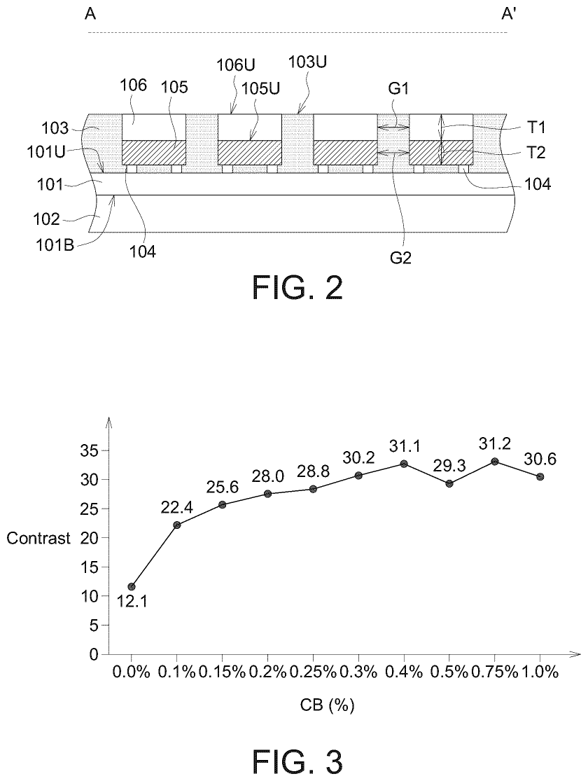

Referring to FIGS. 1 and 2, FIG. 1 illustrates a schematic view of a light-emitting device 10 according to an embodiment of the present disclosure, and FIG. 2 is a schematic cross-sectional view of the light-emitting device 10 illustrated along the line AA′ shown in FIG. 1. The light-emitting device 10 includes a substrate 101, a reflection layer 103, a plurality of light-emitting elements 105, and a plurality of light transmitting elements 106. The substrate 101 has an upper surface 101U and a lower surface 101B. The upper surface 101U may include a circuit layer (not shown). The reflection layer 103 is on the upper surface 101U of the substrate 101. In addition, as shown in FIG. 1, the light-emitting device of the present disclosure may be supported on a carrier substrate 102. Specifically, the reflection layer 103 is on the upper surface 101U of the substrate 101. The lower surface 101B of the substrate 101 is opposite to the upper surface 101U of the substrate 101. The lower surface 101B of the substrate 101 may face the carrier substrate 102, that is, the reflection layer 103 and the carrier substrate 102 are on opposite sides of the substrate 101. In an embodiment, the reflection layer covers all of the upper surface 101U of the substrate 101. In addition, the lower surface 101B may include a circuit layer (not shown), and the carrier substrate 102 may include a drive circuit which electrically connected to the circuit layer of the lower surface 101B to drive a plurality of light-emitting elements 105. For example, the carrier substrate 102 may be various types of circuit boards. In the present disclosure, the substrate 101 and the carrier substrate 102 can be any substrate commonly used in the industry, such as a printed circuit board (PCB), a metal substrate or a ceramic substrate. In an embodiment, the substrate 101 is, for example, a ceramic substrate for providing better heat dissipation, and the carrier substrate 102 is, for example, a metal core printed circuit board (MCPCB) to facilitate fastening by customers.

A plurality of light-emitting elements 105 are in the reflection layer 103 and electrically connected to the circuit layer on the substrate 101. The reflection layer 103 surrounds the side surface of each light-emitting element 105 to achieve reflection. Specifically, a portion of the light emitted by the light-emitting elements 105 may exit the light-emitting elements 105 from the side surfaces of the light-emitting elements 105 and enters the reflection layer 103, and the reflection layer 103 can reflect the incident light to the light transmitting elements 106 to improve the luminous efficiency. A portion of the light emitted by the light-emitting elements 105 may exit the light-emitting elements 105 from the upper surfaces 105U of the light-emitting elements 105 and enters the light transmitting elements 106 without passing through the reflection layer 103. In the present disclosure, the light-emitting element 105 can be any type of light-emitting chip, such as a lateral, vertical or flip light-emitting chip. People skilled in the art can determine the fixing method and electrical connection method according to the type of the chip. For example, in the embodiment shown in FIG. 2, the light-emitting element 105 is a flip type light-emitting chip, which is fixed on the substrate 101 through a plurality of conductive elements 104 and is electrically connected to the circuit layer above it. The conductive element 104 can be a conductive die-bonding material commonly used in the field, such as a solder or a conductive die-bonding paste. In addition, the wavelengths of light emitted by a plurality of light-emitting element 105 can be the same or different from each other.

A plurality of light transmitting elements 106 are disposed on a plurality of light-emitting elements 105 and in the reflection layer 103. The light transmitting elements 106 can be bonded to the light-emitting elements 105 through a transparent adhesive material. The light-emitting elements 105 are protected by a light transmitting elements 106 and the reflection layer 103. From the cross-sectional view of the device, a plurality of light-transmitting elements 106 are separated from each other by the reflection layer 103. The reflection layer 103 may fill the pitches between light transmitting elements 106. The reflection layer 103 may surround the side surface of each light transmitting element 106 so as to reflect light emitted from sidewalls of light transmitting elements 106 to its light exit surface, thereby controlling the light emitting angle and improving contrast and brightness. The base of the light transmitting element 106 can be a polymer material or a ceramic material or a glass material. Preferably, the base of the light transmitting element 106 is a ceramic material to provide better light conversion efficiency (if a light conversion material is within), better protection, better weather resistance and better heat resistance. The upper surface 103U of the reflection layer 103 and the upper surfaces 106U of the light transmitting elements 106 can be coplanar, or the upper surface 103U of the reflection layer 103 may be slightly higher than the upper surfaces 106U of the light transmitting elements 106. The light transmitting elements 106 may include light conversion materials to convert light emitted by a portion of the chips, and the converted light can be combined with the light emitted by the remaining chips to create different colors. The light conversion material may include a fluorescent material, a phosphorescent material, a quantum dot material or any combination thereof, such as yttrium aluminum garnet (YAG) phosphor, silicate phosphor, nitride phosphor and nitrogen oxide phosphor. In an embodiment, blue light-emitting diode chips can be used as the light-emitting elements 105, and yellow YAG phosphor is added into the light transmitting elements 106, such that the light-emitting device 10 can emit white light.

In the present disclosure, the reflection layer 103 includes not only the base and a light reflection material, but also a light absorption material. The base of the reflection layer can be a polymer material; for example, the polymer material may include silicone and epoxy. In an embodiment, the polymer material is a silicone resin. The polymer material can be optically transparent or translucent.

The light reflection material is any suitable material that can improve the light reflection efficiency and/or light extraction efficiency of the reflection layer 103. The light reflection material can be at least one material selected from the group consisting of silicon dioxide (SiO₂), titanium dioxide (TiO₂), boron nitride (BN), aluminum oxide (Al₂O₃) and zirconium dioxide (ZrO₂). In an embodiment, the light reflection material is titanium dioxide. The light reflection material can have a particle size in the range of 0.5 μm to 10 μm. Alternatively, the light reflection material can have a particle size in the range of 1 μm to 7 μm. Alternatively, the light reflection material can have a particle size in the range of 4 μm to 6 μm. In an embodiment, the light reflection material has a particle size of 5 μm. The amount of the light reflection material can be in the range of 40 wt % to 50 wt % based upon the total weight of the reflection layer 103. When the amount of the light reflection material is greater than 50 wt %, the fluidity of precursor of the reflection layer is too poor to be filled into the micrometer scale pitches. When the amount of the light reflection material is less than 20 wt %, the amount of the light reflection material is insufficient to provide reflection effect, which causes the light-emitting device 10 to have low contrast and low luminous flux.

As described above, for micrometer scale pitch, there is a concentration limit for light reflection material. In this case, the present disclosure specifically adds a light absorption material to the reflection layer to further improve contrast. Specifically, adding the light absorption material will reduce the luminous flux, but the present disclosure particularly achieves a balance between contrast and brightness to meet the needs of headlamp for car. The light absorption material can be any suitable material that selectively absorbs or blocks light with specific wavelengths; for example, the light absorption material may include a carbon-containing material such as carbon black, graphene, graphite, carbon nanotubes and any combination thereof. In an embodiment, the light absorption material is carbon black. The amount of the light absorption material can be in the range of 0.15 wt % to 1.0 wt % based upon the total weight of the reflection layer 103. Alternatively, the amount of the light absorption material can be in the range of 0.2 wt % to 0.75 wt % based upon the total weight of the reflection layer 103. When the amount of the light absorption material is less than 0.15 wt %, the absorption of light is insufficient and it is difficult to improve the contrast, as shown in FIG. 3. From the contrast graph shown in FIG. 3, when the amount of the light absorption material approaches 1.0 wt %, the increase in contrast slows down, which means that the increase in contrast is close to the limit; at this time, adding light absorption material will have limited improvement in contrast, but will seriously reduce the luminous flux.

As shown in FIG. 2, there is a micrometer scale pitch G1 in a lateral direction between adjacent two light transmitting elements 106 of a plurality of light transmitting elements 106, there is a micrometer scale pitch G2 in the lateral direction between adjacent two light-emitting elements 105 of a plurality of light-emitting elements 105, and the micrometer scale pitch G1 is substantially equal to or equal to the micrometer scale pitch G2. The lateral direction is perpendicular to the longitudinal direction. The micrometer scale pitch G1 can be in the range of 10 μm to 100 μm. The micrometer scale pitch G2 can be in the range of 10 μm to 100 μm. Specifically, the micrometer scale pitches G1 between a plurality of light transmitting elements 106 can be the same or different from each other, and the micrometer scale pitches G2 between a plurality of light-emitting elements 105 can be the same or different from each other. In an embodiment, the micrometer scale pitch G1 is 25 μm, and the micrometer scale pitch G2 is 25 μm. In the present embodiment, a size of the light transmitting element 106 in the lateral direction (such as a width) can be substantially equal to or equal to a size of the light-emitting element 105 in the lateral direction (such as a width). The side surface of the light transmitting element 106 can be coplanar with the side surface of the light-emitting element 105 below this light transmitting element 106.

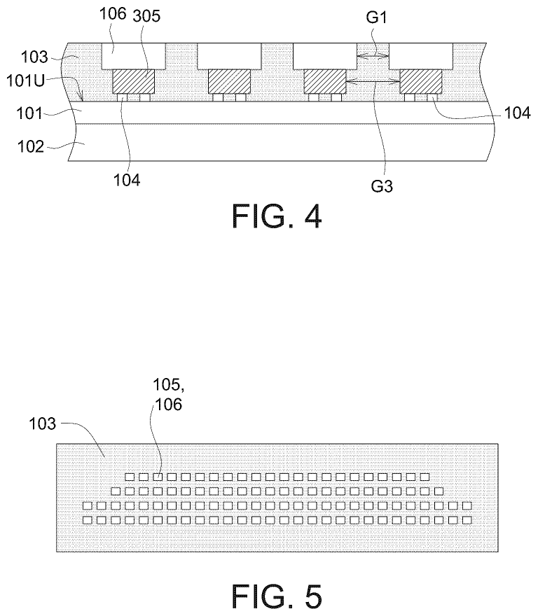

In other embodiments, the micrometer scale pitch between adjacent two light transmitting elements 106 of a plurality of light transmitting elements 106 can be smaller than the micrometer scale pitch between adjacent two light-emitting elements 105 of a plurality of light-emitting elements 105, as shown in FIG. 4. In FIG. 4, there is a micrometer scale pitch G1 in the lateral direction between adjacent two light transmitting elements 106 of a plurality of light transmitting elements 106, there is a micrometer scale pitch G3 in the lateral direction between adjacent two light-emitting elements 305 of a plurality of light-emitting elements 305, and the micrometer scale pitch G1 is smaller than the micrometer scale pitch G3. The micrometer scale pitches G3 between a plurality of light-emitting elements 305 can be the same or different from each other. The micrometer scale pitch G3 can be in the range of 10 μm to 100 μm. In the present embodiment, a size of the light transmitting element 106 in the lateral direction (such as a width) can be greater than a size of the light-emitting element 305 in the lateral direction (such as a width).

Referring back to FIGS. 1 and 2, the light transmitting element 106 has a thickness T1 in the longitudinal direction, and the light-emitting element 105 has a thickness T2 in the longitudinal direction. The thickness T1 of the light transmitting element 106 can be in the range of 50 μm to 150 μm. When the thickness T1 of the light transmitting element 106 is greater than 150 μm, the contrast will drop significantly. When the thickness T1 of the light transmitting element 106 is less than 50 μm, the light transmitting element 106 is easily broken. The thickness T2 of the light-emitting element 105 can be in the range of 50 μm to 150 μm. When the thickness T2 of the light-emitting element 105 is greater than 150 μm, the contrast will drop significantly. When the thickness T2 of the light-emitting element 105 is less than 50 μm, the light-emitting element 105 is easily broken. The thicknesses of a plurality of light transmitting elements 106 in the longitudinal direction can be the same or different from each other. The thicknesses of a plurality of light-emitting elements 105 in the longitudinal direction can be the same or different from each other.

The light-emitting device 10 of the present disclosure can include any number of light-emitting elements 105 and any number of light transmitting elements 106, and any number of light-emitting elements 105 and any number of light transmitting elements 106 can be arranged as a light-emitting array in any arrangement. For example, the light-emitting device includes 102 light-emitting elements 105 and 102 light transmitting elements 106, and 102 light-emitting elements 105 and 102 light transmitting elements 106 can be arranged as a light-emitting array as shown in FIG. 5. FIG. 5 illustrates a schematic top view of a light-emitting device and merely shows the light-emitting elements 105, the light transmitting elements 106 and the reflection layer 103 in the light-emitting device; the other elements in the light-emitting device are shown in FIGS. 1, 2 and 4.

The present disclosure is explained below with reference to examples and comparative examples. However, the present disclosure is not limited to the compositions, amounts, and particle sizes disclosed by the following examples.

A light-emitting device is prepared according to the structures shown in FIGS. 1 and 2. A polymer material and a light reflection material are mixed according to the compositions and amounts shown in the following TABLE 1, the mixed material is filled between the light-emitting elements and the light transmitting elements to form a reflection layer, and light-emitting devices of Examples 1 to 6 and Comparative Example 1 are obtained. The area of the light-emitting element and the light transmitting element is approximately 50 μm×50 μm, the thickness of the light transmitting element is 120 μm, the thickness of the light-emitting element is 150 μm, and all of the micrometer scale pitches G2 are 25 μm. In the Examples 1 to 6 and Comparative Example 1, the polymer material is transparent silicone, the light reflection material is titanium dioxide, and the amount of light reflection material is based upon the total weight of the reflection layer. The light-emitting device of Comparative Example 1 does not include a reflection layer, and there are air gaps between light-emitting elements and light transmitting elements. The contrast of the light-emitting devices of Examples 1 to 6 and Comparative Example 1 is measured by the following measurement apparatus, parameters and measurement methods, and the results are listed in the following TABLE 1.

### [Measurement Apparatus and Parameters]

Measurement apparatus: LumiCam 2400B (Instrument Systems)
Lenses: Canon 24 mm and OD4 filter
Iris F/number: 16
Distance between the sample and the Measurement apparatus: 0.3 m

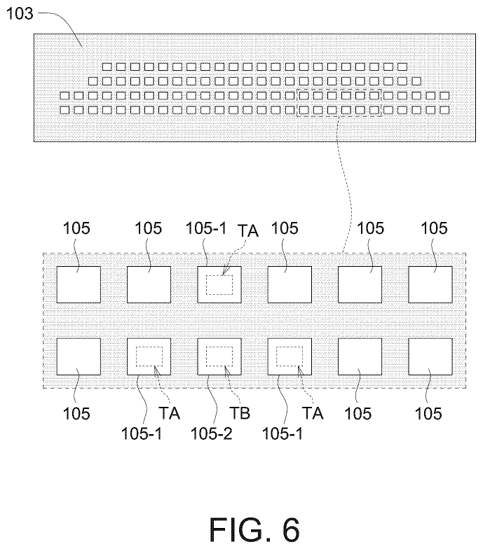

Take the light-emitting device (sample) shown in FIG. 6 as an example, a current of 10 mA is used to cause all the light-emitting elements in the light-emitting device (including light-emitting elements 105 and 105-1) except the light-emitting element 105-2 to emit light, that is, the light-emitting element 105-2 is intentionally not allowed to emit light. LumiCam 2400B Imaging apparatus is used to measure the brightness (cd/mm²) of a detection area TB in the light-emitting element 105-2 that does not emit light, and the brightness of each of the three detection areas TA in three light-emitting elements 105-1 adjacent to the light-emitting element 105-2 that does not emit light. The average value of the brightness of the three detection areas TA are calculated, and the brightness of the detection area TB is divided by the average value of brightness of the detection areas TA to obtain the contrast. The area of the detection area TA is 300 μm×300 μm. The area of the detection area TB is 300 μm×300 μm.

TABLE 1

| | Light reflection material | | | | |
|---|---|---|---|---|---|
| | Particle | | | | Completeness |
| | size | | Amount | Contrast | of pitch filling |
| Example 1 | 5 | μm | 20 wt % | 2.6 | Complete |
| Example 2 | 5 | μm | 45 wt % | 6.9 | Complete |
| Example 3 | 0.5 | μm | 40 wt % | 3.5 | Complete |
| Example 4 | 0.5 | μm | 50 wt % | 3.9 | Complete |
| Comparative | — | | — | 2.3 | Complete |
| Example 1 | | | | | |
| Comparative | 5 | μm | 60 wt % | 10.1 | Incomplete |
| Example 2 | | | | | |
| Comparative | 0.5 | μm | 60 wt % | 5.57 | Incomplete |

Example 3

As shown in TABLE 1, when the light reflection material is added to the polymer material, the contrast in the case of a light reflection material with a particle size of 5 μm is better than the contrast in the case of a light reflection material with a particle size of 0.5 μm. In general, when the amount of the light reflection material is in the range of 20 wt % to 50 wt %, the contrast of the light-emitting device is improved. When the amount of the light reflection material increases to 60 wt %. no matter whether the light reflection material with a particle size of 5 μm or 0.5 μm is used, the fluidity of precursor of the reflection layer is too poor so that some pitches cannot be filled, which means that the light-emitting elements cannot be completely protected.

A light-emitting device is prepared according to the structures shown in FIGS. 1 and 2. A polymer material, a light reflection material, and a light absorption material are mixed according to the compositions and amounts shown in the following TABLE 2, the mixed material is filled between the light-emitting elements and the light transmitting elements to form a reflection layer, and light-emitting devices of Examples 5 to 12 and Comparative Examples 4 to 6 are obtained. In the Examples 5 to 12 and Comparative Examples 4 to 6, the area of the light-emitting element and the light transmitting element is approximately 525 μm×65 μm, the thickness of the light transmitting element is 120 μm, the thickness of the light-emitting element is 100 μm, and all of the micrometer scale pitches G2 are 25 μm. In the Examples 5 to 12 and Comparative Examples 4 to 6, the polymer material is transparent silicone, the light reflection material is titanium dioxide, the light absorption material is carbon black, and the amounts of light reflection material and light absorption material are based upon the total weight of the reflection layer. The reflection layer of the light-emitting device of Comparative Example 5 does not include a light absorption material. The light-emitting device of Comparative Example 6 does not include a reflection layer, and there are air gaps between light-emitting elements and light transmitting elements. The contrast and luminous flux of the light-emitting devices of Examples 5 to 12 and Comparative Examples 4 to 6 are measured by the above measurement apparatus and parameters, and the results are listed in the following TABLE 2.

TABLE 2

| | Light reflection | | | | Light | | | Luminous |
|---|---|---|---|---|---|---|---|---|
| | material | | | | absorption | | | flux |
| | Particle | | | | material | | | (lm, |
| | size | | Amount | | Amount | | Contrast | cd/m²) |
| Example 5 | 5 | μm | 45 | wt % | 0.15 | wt % | 25.6 | 72.17 |
| Example 6 | 5 | μm | 45 | wt % | 0.2 | wt % | 28.0 | 68.83 |
| Example 7 | 5 | μm | 45 | wt % | 0.25 | wt % | 28.8 | 64.71 |
| Example 8 | 5 | μm | 45 | wt % | 0.3 | wt % | 30.2 | 60.04 |
| Example 9 | 5 | μm | 45 | wt % | 0.4 | wt % | 31.1 | 54.78 |
| Example 10 | 5 | μm | 45 | wt % | 0.5 | wt % | 29.3 | 53.97 |
| Example 11 | 5 | μm | 45 | wt % | 0.75 | wt % | 31.2 | 48.74 |
| Example 12 | 5 | μm | 45 | wt % | 1.0 | wt % | 30.6 | 39.50 |
| Comparative | 5 | μm | 45 | wt % | 0.1 | wt % | 22.4 | 75.3 |
| Example 4 | | | | | | | | |
| Comparative | 5 | μm | 45 | wt % | 0 | wt % | 12.1 | 82.05 |

| | | | | | |
|---|---|---|---|---|---|
| Example 5 | | | | | |
| Comparative | — | — | — | 4.0 | — |
| Example 6 | | | | | |

As compared with Examples 1 to 4 shown in TABLE 1, the thicknesses of the light-emitting elements in Example 5 to 12 shown in TABLE 2 are decreased and additional light absorption materials are added to the reflection layers. Comparing Example 2 and Comparative Example 5, it can be seen that the contrast is improved when the thickness of the light-emitting element is reduced. In addition, when the amount of the light absorption material is in the range of 0.15 wt % to 1.0 wt %, the contrast of the light-emitting device is high and the luminous flux is maintained within an appropriate range without being too low, which means that a good balance between contrast and luminous flux is achieved and the luminous efficiency of the light-emitting device is improved. Although the light-emitting device of Comparative Example 4 exhibits high luminous flux, it exhibits poor contrast. The contrast of the light-emitting device of Comparative Example 5 is smaller than that of the light-emitting devices of Example 5 to 12, which means that the use of the light absorption material in the reflection layer can improve contrast. The contrast of the light-emitting device of Comparative Example 6 is much smaller than that of the light-emitting devices of Example 5 to 12, which means that the use of the material combination of the reflection layer of the present disclosure can significantly improve the contrast.

As shown in TABLE 2, the light-emitting devices of the present disclosure exhibit a contrast greater than or equal to 25 and a luminous flux greater than or equal to 39 Im, which means that a good balance between contrast and luminous flux can be maintained while ensuring high contrast. Therefore, the light-emitting device of the present disclosure has a good contrast and a good luminous flux, and luminous efficiency, heat dissipation, reliability and performance can be improved. Moreover, the present disclosure uses packaging technology to directly arrange the light-emitting diode chip on the substrate to form a light-emitting device with micrometer scale pitches, the arrangement and number of the light-emitting elements can be easily changed to adapt to different situations, and the present disclosure contributes to minimize the light-emitting device.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in light-emitting devices and light-emitting diodes, the shapes or positional relationship of the elements and the procedure details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A light-emitting device, comprising:
a substrate;
a reflection layer on the substrate;
a plurality of light-emitting elements on the substrate and in the reflection layer; and
a plurality of light transmitting elements on the plurality of light-emitting elements and in the reflection layer, wherein a plurality of upper surfaces of the plurality of light transmitting elements are exposed by the reflection layer, and there is a first micrometer scale pitch between adjacent two light transmitting elements of the plurality of light transmitting elements,
wherein the reflection layer comprises a light reflection material and a light absorption material.

2. The light-emitting device according to claim 1, wherein the amount of the light absorption material is in the range of 0.15 wt % to 1.0 wt % based upon a total weight of the reflection layer.

3. The light-emitting device according to claim 1, wherein the plurality of light transmitting elements comprise wavelength conversion materials.

4. The light-emitting device according to claim 1, wherein the plurality of light-emitting elements are separated from each other by the reflection layer, and the plurality of light transmitting elements are separated from each other by the reflection layer.

5. The light-emitting device according to claim 1, wherein there is a second micrometer scale pitch between adjacent two light-emitting elements of the plurality of light-emitting elements, and the first micrometer scale pitch is smaller than or equal to the second micrometer scale pitch.

6. The light-emitting device according to claim 5, wherein the first micrometer scale pitch is in the range of 10 μm to 100 μm.

7. The light-emitting device according to claim 1, wherein an upper surface of the reflection layer and an upper surface of the plurality of light transmitting elements are coplanar.

8. The light-emitting device according to claim 1, further comprising:
a plurality of conductive elements on the substrate and between the substrate and the plurality of light-emitting elements, wherein each of the plurality of light-emitting elements electrically connected to two conductive elements of the plurality of conductive elements.

9. The light-emitting device according to claim 1, wherein the amount of the light absorption material is in the range of 0.2 wt % to 0.75 wt % based upon a total weight of the reflection layer.

10. The light-emitting device according to claim 1, wherein the light reflection material has a particle size in the range of 0.5 μm to 10 μm.

11. The light-emitting device according to claim 1, wherein the amount of the light reflection material is in the range of 20 wt % to 50 wt % based upon a total weight of the reflection layer.

12. The light-emitting device according to claim 1, wherein the reflection layer comprises a polymer material.

13. The light-emitting device according to claim 1, wherein the light absorption material is carbon black.

14. The light-emitting device according to claim 1, wherein the light reflection material is selected from the group consisting of SiO₂, TiO₂, BN, Al₂O₃ and ZrO₂.

15. The light-emitting device according to claim 1, wherein the light-emitting device has a contrast greater than or equal to 25.

16. The light-emitting device according to claim 1, wherein the light-emitting device has a luminous flux greater than or equal to 39 Im.
